(19) United States
(12) Patent Application Publication
(10) Pub. No.: US 2019/0035951 A1
(43) Pub. Date: Jan. 31, 2019

(54) COMPOSITION FOR SOLAR CELL ELECTRODE AND ELECTRODE PREPARED USING THE SAME

(71) Applicant: Samsung SDI Co., Ltd., Yongin-si (KR)

(72) Inventors: Min Young LEE, Suwon-si (KR); Dong Suk KIM, Suwon-si (KR)

(21) Appl. No.: 15/970,118

(22) Filed: May 3, 2018

(30) Foreign Application Priority Data
Jul. 28, 2017 (KR) 10-2017-0096540

(51) Int. Cl. H01L 31/0224; H01L 31/18; C03C 8/18

(52) U.S. Cl. CPC H01L 31/022425; C03C 8/18; H01L 31/18; H01L 31/022466

(57) ABSTRACT

A composition for a solar cell electrode includes a conductive powder, a glass frit that contains tellurium (Te), lithium (Li), zinc (Zn), and oxygen (O), the glass frit having a tap density of about 0.8 g/ml to about 1.55 g/ml, and an organic vehicle

### CROSS-REFERENCE TO RELATED APPLICATION

Korean Patent Application No. 10-2017-0096540, filed on Jul. 28, 2017 in the Korean Intellectual Property Office, and entitled: “Composition for Solar Cell Electrode and Electrode Prepared Using the Same,” is incorporated by reference herein in its entirety.

### BACKGROUND

### 1. Field

Embodiments relate to a composition for a solar cell electrode and an electrode prepared using the same.

### 2. Description of the Related Art

Solar cells may generate electric energy using the photovoltaic effect of a p-n junction, which may convert photons of sunlight into electricity. In the solar cell, front and rear electrodes may be formed on upper and lower surfaces of a semiconductor wafer or substrate with the p-n junctions, respectively. The photovoltaic effect of the p-n junction may be induced by sunlight entering the semiconductor wafer. Electrons generated by the photovoltaic effect of the p-n junction may provide electric current to the outside through the electrodes.

### SUMMARY

Embodiments are directed to a composition for a solar cell electrode including a conductive powder, a glass frit that contains tellurium (Te), lithium (Li), zinc (Zn), and oxygen (O), the glass frit having a tap density of about 0.8 g/ml to about 1.55 g/ml, and an organic vehicle.

The glass frit may be formed of a metal oxide including about 25 mol % to about 45 mol % of tellurium oxide (TeO₂), about 25 mol % to about 40 mol % of lithium oxide (Li₂O), and about 15 mol % to about 35 mol % of zinc oxide (ZnO).

The glass frit may be formed of a mixture of components that consists essentially of 34 mol % to 39 mol % of tellurium oxide (TeO₂), 24 mol % to 33 mol % of lithium oxide (Li₂O), 17 mol % to 22 mol % of zinc oxide (ZnO), 7 mol % to 12 mol % of boron oxide (B₂O₃), 5 mol % to 7 mol % of magnesium oxide (MgO₂), and 0 mol % to 1 mol % of tungsten oxide (WO₃), provided that mole percentages of the TeO₂, Li₂O, ZnO, B₂O₃, MgO₂, and WO₃ are limited to combinations thereof providing a tap density of about 0.8 g/ml to about 1.55 g/ml.

The glass frit may be formed of a metal oxide including tellurium oxide (TeO₂), lithium oxide (Li₂O), and zinc oxide (ZnO), and may satisfy the following Formula 1, wherein M_{TeO2} represents mol % of TeO₂, M_{Li2O} represents mol % of Li₂O, and M_{ZnO} represents mol % of ZnO,

0 mol %≤|M_{TeO2}−M_{Li2O}|+|M_{Li2O}−M_{ZnO}|+|M_{ZnO}−M_{TeO2}|≤about 60 mol %. [Formula 1]

The glass fit may not include bismuth (Bi) and may not include lead (Pb).

The glass frit may have a particle size of about 0.1 μm to about 10 μm.

The glass frit may further include at least one of sodium (Na), phosphorous (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), or boron (B).

The composition may include about 60 wt % to about 95 wt % of the conductive powder, about 0.1 wt % to about 20 wt % of the glass frit, and about 1 wt % to about 30 wt % of the organic vehicle.

The composition may further include at least one of a dispersing agent, a thixotropic agent, a plasticizer, a viscosity stabilizer, an antifoaming agent, a pigment, an ultraviolet stabilizer, an antioxidant, or a coupling agent.

Embodiments are also directed to a solar cell electrode prepared from the composition for a solar cell electrode according to an embodiment.

Embodiments are also directed to a method of preparing a solar cell electrode, the method including providing a substrate having a p-n junction, the substrate having a light-receiving surface and a back surface, applying, to the light-receiving surface, the composition according to an embodiment, and baking the substrate having the composition applied thereto.

### BRIEF DESCRIPTION OF THE DRAWINGS

Features will become apparent to those of skill in the art by describing in detail example embodiments with reference to the attached drawings in which:

FIG. 1 illustrates a schematic view of a solar cell according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

As used herein, the terms such as “comprise”, “comprising”, “have”, “having”, “include”, and “including”, when used in this specification, specify the presence of the stated features, integers, steps, operations, elements, and/or components, but do not preclude the presence or addition of one or more other features, integers, steps, operations, elements, components, and/or groups thereof, unless the term “only” is used. As used herein, the singular forms “a” and “an” are intended to include the plural forms as well, unless the context clearly indicates otherwise.

In construing elements of embodiment, it is regarded to include an error range even though there is no distinctive description.

As used herein, the term “metal oxide” refers to a single metal oxide or a plurality of metal oxides.

As used herein, the term denoting a range “X to Y” refers to “at least X and no greater than Y”.

Composition for a Solar Cell Electrode

A composition for a solar cell electrode according to an embodiment may include a conductive powder, a glass frit that contains tellurium (Te), lithium (Li), zinc (Zn), and oxygen (O) (a Te-Li-Zn-O-based glass frit), and an organic vehicle, and the glass frit may have a density of about 0.8 g/ml to about 1.55 g/ml.

Now, each component of the composition for a solar cell electrode will be described in more detail.

Conductive Powder

The conductive powder may serve to impart electrical conductivity to the composition for a solar cell electrode. The composition for a solar cell electrode may include a metal powder such as silver (Ag) or aluminum (Al) as the conductive powder. For example, the conductive powder may include silver powder. The conductive powder may have a nanometer or micrometer-scale particle size. For example, the conductive powder may include silver powder having a particle size of dozens to several hundred nanometers, or having a particle size of several to dozens of micrometers. In some implementations, the conductive powder may include a mixture of two or more types of silver powder having different particle sizes.

The conductive powder may have various particle shapes, such as a spherical, flake, or amorphous particle shape, etc.

The conductive powder may have an average particle size (D50) of about 0.1 μm to about 10 μm, for example about 0.5 μm to about 5 μm. The average particle size may be measured using, for example, a Model 1064LD (CILAS Co., Ltd.) particle size analyzer after dispersing the conductive powder in isopropyl alcohol (IPA) at 25° C. for about 3 minutes via ultrasonication. Within this range, contact resistance and line resistance of a solar cell electrode may be reduced.

The conductive powder may be present in the composition for a solar cell electrode in an amount of about 60 wt % to about 95 wt %, for example about 70 wt % to about 90 wt %. Within this range, conversion efficiency of a solar cell including the composition may improve and the composition may be easily prepared in paste form. For example, the conductive powder may be present in the composition for a solar cell electrode in an amount of about 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt %.

Te-Li-Zn-O-Based Glass Frit

The glass frit may serve to form metal crystal grains in an emitter region by etching an anti-reflection layer and melting the conductive powder during a baking process of the composition for a solar cell electrode. The glass frit may enhance adhesion between the conductive powder and the wafer. During the baking process, the glass frit may soften and decrease the baking temperature.

In some implementations, a Te-Li-Zn-O-based glass frit may be used, and the glass frit may have a density of about 0.8 g/ml to about 1.55 g/ml. With this range, a dispersity of the glass frit in the composition may improve, which may help enable uniform etching, and series resistance of a solar cell may be reduced while conversion efficiency is enhanced. In example embodiments, the glass frit may have a density of about 0.8 g/ml, 0.85 g/ml, 0.9 g/ml, 0.95 g/ml, 1.0 g/ml, 1.05 g/ml, 1.1 g/ml, 1.15 g/ml, 1.2 g/ml, 1.25 g/ml, 1.3 g/ml, 1.35 g/ml, 1.4 g/ml, 1.45 g/ml, 1.5 g/ml, or 1.55 g/ml.

The density of the glass frit may represent a density measured after melting, quenching, and pulverization of a metal oxide for the glass fit.

The Te-Li-Zn-O-based glass fit may be prepared from a metal oxide including tellurium oxide (TeO₂), lithium oxide (Li₂O), and zinc oxide (ZnO). For example, the metal oxide may be mixed using a ball mill or a planetary mill. The mixed composition may be melted at about 900° C. to about 1300° C., followed by quenching to 25° C. The obtained resultant may be subjected to pulverization using, for example, a disk mill or a planetary mill. The pulverized glass frit may have an average particle size (D50) of about 0.1 μm to about 10 μm.

In some implementations, the glass frit may be formed of a metal oxide including about 25 mol % to about 45 mol % of tellurium oxide (TeO₂), about 25 mol % to about 40 mol % of lithium oxide (Li₂O), and about 15 mol % to about 35 mol % of zinc oxide (ZnO). Within this range, the density of the glass frit may be regulated within a scope of the embodiments, and electrical characteristics of a solar cell including the glass frit may be well balanced.

The glass frit may be formed of a metal oxide including tellurium oxide (TeO₂), lithium oxide (Li₂O), and zinc oxide (ZnO), and the glass frit may satisfy the following Formula 1:

0 mol %≤|M_{TeO2}−M_{Li2O}|+|M_{Li2O}−M_{ZnO}|+|M_{ZnO}−M_{TeO2}|≤about 60 mol % [Formula 1]

wherein, in Formula 1 above,

M_{TeO2} represents mol % of tellurium oxide (TeO₂),

M_{Li2O} represents mol % of lithium oxide (Li₂O), and

M_{ZnO} represents mol % of zinc oxide (ZnO).

A sum of absolute values between tellurium oxide (TeO₂) and lithium oxide (Li₂O), between lithium oxide (Li₂O) and zinc oxide (ZnO), and between zinc oxide (ZnO) and tellurium oxide (TeO₂), according to Formula 1 above, may range from 0 mol % to about 60 mol %, for example 0 mol % to about 50 mol %, for example 0 mol % to about 40 mol %. Within this range, electrical characteristics of a solar cell electrode including the glass fit may be well balanced, ultimately improving conversion efficiency.

The glass frit may be formed of a metal oxide having a mole ratio of tellurium oxide (TeO₂) to lithium oxide (Li₂O) ranging from about 1:1 to about 2:1, for example about 1:1 to about 1.5:1. Within this range, the glass frit may be well dispersed in a composition for a solar cell, which may help provide uniform etching.

The glass fit may be formed of a metal oxide having a mole ratio of lithium oxide (Li₂O) to zinc oxide (ZnO) ranging from about 1:1 to about 3:1, for example about 1:1 to about 2:1. Within this range, a solar cell electrode including the glass frit may have low series resistance Rs.

The glass frit may be formed of a metal oxide having a mole ratio of tellurium oxide (TeO₂) to zinc oxide (ZnO) ranging from about 1:1 to about 3.5:1, for example about 1:1 to about 2.5:1. Within this range, a solar cell electrode including the glass frit may have excellent conversion efficiency.

The glass frit may not include bismuth (Bi) nor lead (Pb). In this case, electrical characteristics such as series resistance, open circuit voltage, an aspect ratio of an electrode, conversion efficiency, and fill factor may be well balanced, and density control of the glass frit may become easier.

The glass frit may further include at least one of sodium (Na), phosphorous (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), and boron (B).

In some implementations, the glass frit may further include at least one of boron (B), tungsten (W), and magnesium (Mg).

The glass frit may be present in the composition for a solar cell electrode in an amount of about 0.1 wt % to about 20 wt %, for example about 0.5 wt % to about 10 wt %. Within this range, a p-n junction stability under a variety of surface resistance may be secured and resistance of a solar cell may be reduced, ultimately improving efficiency of the solar cell. In some implementations, the glass frit may present in the composition for a solar cell electrode in an amount of about 0.1 wt %, 0.5 wt %, 1 wt %, 1.5 wt %, 2 wt %, 2.5 wt %, 3 wt %, 3.5 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %.

(3) Organic Vehicle

The organic vehicle may impart suitable viscosity and rheological characteristics for printing to the composition for a solar cell electrode through mechanical mixing with the inorganic component of the composition.

The organic vehicle may be a suitable organic vehicle used in a composition for a solar cell electrode. The organic vehicle may include a binder resin, a solvent, or the like.

The binder resin may be selected from acrylate resins or cellulose resins. For example, ethyl cellulose may be used as the binder resin. In some implementations, the binder resin may be selected from ethyl hydroxyethyl cellulose, nitrocellulose, a mixture of ethyl cellulose and a phenol resin, alkyd, phenol, acrylate ester, xylene, polybutene, polyester, urea, melamine, vinyl acetate resins, wood rosin, polymethacrylates of alcohols, or the like.

The solvent may be selected from, for example, hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methyl ethyl ketone, benzyl alcohol, γ-butyrolactone, and ethyl lactate. These may be used alone or in a mixture thereof.

The organic vehicle may be present in the composition for a solar cell electrode in an amount of about 1 wt % to about 30 wt %. Within this range, the organic vehicle may provide sufficient adhesive strength and excellent printability to the composition. For example, the organic vehicle may be present in the composition for a solar cell electrode in an amount of about 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %.

(4) Additive

The composition for a solar cell electrode may further include a general additive to enhance fluidity, process properties, or stability, as desired. The additive may include one or more of a dispersant, a thixotropic agent, a plasticizer, a viscosity stabilizer, an anti-foaming agent, a pigment, an ultraviolet stabilizer, an antioxidant, a coupling agent, or the like. The additive may be used alone or in a mixture thereof. The additive may be present in an amount of, for example, about 0.1 wt % to about 5 wt % based on the total weight of the composition for a solar cell electrode. For example, the additive may be present in an amount of about 0.1 wt %, 0.2 wt %, 0.3 wt %, 0.4 wt %, 0.5 wt %, 0.6 wt %, 0.7 wt %, 0.8 wt %, 0.9 wt %, 1 wt %, 1.5 wt %, 2 wt %, 2.5 wt %, 3 wt %, 3.5 wt %, 4 wt %, 4.5 wt %, or 5 wt %, based on the total weight of the composition for a solar cell electrode.

Solar Cell Electrode and Solar Cell Including the Same

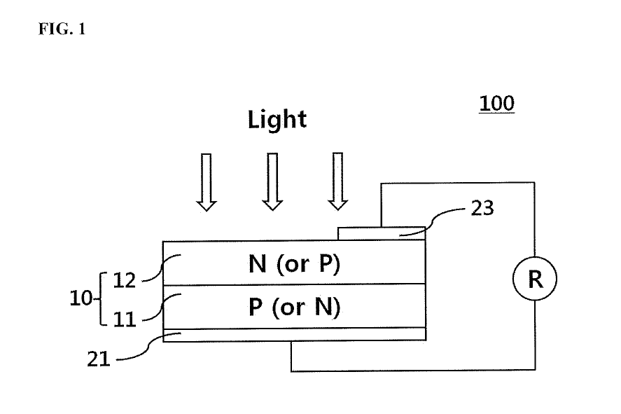

Embodiments are related to an electrode formed of the composition for a solar cell electrode and a solar cell including the same. FIG. 1 illustrates a solar cell in accordance with an embodiment.

Referring to FIG. 1, a solar cell 100 according to an embodiment may include a substrate 10, a front electrode 23 formed on a front surface of the substrate 10, and a rear electrode 21 formed on a back surface of the substrate 10.

In an embodiment, the substrate 10 may include a substrate with a p-n junction formed thereon. For example, the substrate 10 may include a semiconductor substrate 11 and an emitter 12. For example, the substrate 10 may include a substrate prepared by doping one surface of a p-type semiconductor substrate 11 with an n-type dopant to form an n-type emitter 12. In some implementations, the substrate 10 may include a substrate prepared by doping one surface of an n-type semiconductor substrate 11 with a p-type dopant to form a p-type emitter 12. The semiconductor substrate 11 may be one of a p-type substrate and an n-type substrate. The p-type substrate may be a semiconductor substrate doped with a p-type dopant, and the n-type substrate may be a semiconductor substrate doped with an n-type dopant.

In the description of the substrate 10, the semiconductor substrate 11, or the like, a surface of such a substrate on which light is incident is generally referred to as a “front surface” (light receiving surface), and a surface of the substrate opposite the front surface is referred to as a “back surface.”

In an embodiment, the semiconductor substrate 11 may be formed of crystalline silicon or a compound semiconductor. The crystalline silicon may be monocrystalline or polycrystalline silicon. As an example of the crystalline silicon, a silicon wafer may be used.

The p-type dopant may be a material including a group III element such as boron, aluminum, or gallium. The n-type dopant may be a material including a group V element, such as phosphorus, arsenic, or antimony.

The front electrode 23 and/or the rear electrode 21 may be prepared using the composition for a solar cell electrode according to embodiments. For example, the front electrode 23 may be prepared using the composition including silver powder as the conductive powder, and the rear electrode 21 may be prepared using the composition including aluminum powder as the conductive powder. The front electrode 23 may be formed by printing the composition for a solar cell electrode according to an embodiment onto the emitter 12, followed by baking. The rear electrode 21 may be formed by applying the composition for a solar cell electrode according to an embodiment onto the back surface of the semiconductor substrate 11, followed by baking.

Next, embodiments will be described in more detail with reference to examples. The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE 1

As an organic binder, 1.5 wt % of ethyl cellulose (STD4, Dow Chemical Company) was sufficiently dissolved in 6.4 wt % of butyl carbitol at 60° C., and 86.8 wt % of spherical silver powder (AG-4-8, Dowa Hightech Co., Ltd.) having an average particle size of 2.0 μm, 2.0 wt % of a glass frit prepared according to the components as listed in Table 1, 3 wt % of a dispersant BYK102 (BYK-chemie), and 0.3 wt % of a thixotropic agent Thixatrol ST (Elementis Co., Ltd.) were added to the binder solution, followed by mixing and kneading in a 3-roll kneader, thereby preparing a composition for a solar cell electrode.

### EXAMPLES 2 TO 5 AND COMPARATIVE EXAMPLES 1 TO 6

Compositions for solar cell electrodes were prepared in the same manner as in Example 1 except that glass frits described in Table 1 were used, respectively.

TABLE 1

| | | | | | | | | Density of |
|---|---|---|---|---|---|---|---|---|
| | | | | | | | | glass frit |
| (mol %) | TeO₂ | Li₂O | ZnO | B₂O₃ | WO₃ | MgO₂ | Total | (g/ml) |
| Example 1 | 36 | 33 | 17 | 9 | — | 5 | 100 | 0.80 |
| Example 2 | 34 | 32 | 16 | 12 | 1 | 5 | 100 | 1.10 |
| Example 3 | 34 | 29 | 21 | 10 | — | 6 | 100 | 1.30 |
| Example 4 | 39 | 24 | 22 | 7 | 1 | 7 | 100 | 1.50 |
| Example 5 | 36 | 28 | 19 | 10 | 1 | 6 | 100 | 1.55 |
| Comparative Example 1 | 30 | 34 | 17 | 13 | 1 | 5 | 100 | 0.70 |
| Comparative Example 2 | 36 | 25 | 22 | 9 | 2 | 6 | 100 | 1.65 |
| Comparative Example 3 | 34 | 29 | 19 | 10 | 2 | 6 | 100 | 1.70 |
| Comparative Example 4 | 34 | 29 | 19 | 9 | 1 | 8 | 100 | 1.90 |
| Comparative Example 5 | 40 | 29 | 20 | 3 | 1 | 7 | 100 | 2.20 |
| Comparative Example 6 | 40 | 35 | — | 16 | 3 | 6 | 100 | 1.50 |

Evaluation of Properties

(1) Density of a Glass Frit (g/ml)

A metal oxide having components as described in Table 1 was subjected to mixing using a ball mill, followed by melting at 1,000° C. and quenching to 25° C. The obtained resultant was subjected to pulverization using a disk mill to prepare a glass frit. A density of the prepared glass frit was measured using a Tap density measurement and the results are shown in Table 1 and Table 2.

(2) Series Resistance (Rs, mΩ)

The pastes for solar cell electrodes prepared in the Examples and Comparative Examples were deposited onto a front surface of a wafer by screen-printing in a predetermined pattern, followed by drying in an IR drying furnace. Cells formed according to this procedure were subjected to baking at 600° C. to 900° C. for 60 seconds to 210 seconds in a belt-type baking furnace, and then evaluated as to series resistance (Rs) using a TLM (Transfer Length Method) tester. The measured results are shown in Table 2.

(3) Fill Factor (%) and Efficiency (%)

The pastes for solar cell electrodes prepared in the Examples and Comparative Examples were deposited onto a front surface of a wafer by screen-printing in a predetermined pattern, followed by drying in an IR drying furnace. Then, an aluminum paste was printed on a rear side of the wafer and dried in the same manner as above. Cells formed according to this procedure were subjected to baking at 400° C. to 900° C. for 30 seconds to 180 seconds in a belt-type baking furnace, and evaluated as to Fill Factor (%), and conversion efficiency (Eff., %) using a solar cell efficiency tester CT-801 (Pasan Co., Ltd.). The measured results are shown in Table 2.

TABLE 2

| | Density of | Series | Fill | |
|---|---|---|---|---|
| | glass frit | resistance | Factor | Eff. |
| | (g/ml) | (mΩ) | (%) | (%) |
| Example 1 | 0.80 | 2.21 | 78.87 | 17.925 |
| Example 2 | 1.10 | 2.18 | 78.74 | 17.910 |
| Example 3 | 1.30 | 2.17 | 78.69 | 17.897 |
| Example 4 | 1.50 | 2.09 | 78.84 | 17.920 |
| Example 5 | 1.55 | 2.12 | 78.72 | 17.900 |
| Comparative Example 1 | 0.70 | 2.42 | 78.25 | 17.601 |
| Comparative Example 2 | 1.65 | 2.33 | 78.39 | 17.739 |
| Comparative Example 3 | 1.70 | 2.29 | 78.59 | 17.796 |
| Comparative Example 4 | 1.90 | 2.31 | 78.46 | 17.758 |
| Comparative Example 5 | 2.20 | 2.45 | 78.17 | 17.584 |
| Comparative Example 6 | 1.50 | 2.52 | 77.89 | 17.465 |

As shown in Table 2, it can be seen that each electrode for a solar cell prepared from the compositions of Examples 1 to 5 had low series resistance and high conversion efficiency.

Conversely, each electrode for a solar cell prepared from the compositions of Comparative Examples 1 to 5 in which the glass frit had a density outside the scope of the embodiments had increased series resistance and low conversion efficiency. In addition, the electrode prepared from the composition of Comparative Example 6 in which the glass frit did not include zinc had high series resistance and low fill factor, together with low conversion efficiency.

By way of summation and review, the electrodes of the solar cell may be formed on the wafer by applying, patterning, and baking a composition for a solar cell electrode. A conductive paste composition including a conductive powder, a glass frit, and an organic vehicle may be used as the composition for a solar cell electrode. The glass frit in the conductive paste composition may serve to dissolve an anti-reflection layer formed on the semiconductor wafer and electrically connect the conductive powder to the semiconductor wafer. The glass frit may affect electrical characteristics of the solar cell, such as open circuit voltage Voc, series resistance Rs, or the like, in addition to an aspect ratio of the solar cell electrode. Thus, conversion efficiency and fill factor of the solar cell may be changed accordingly.

As described above, embodiments may provide a composition for a solar cell electrode which has good glass frit dispersity which may help provide uniform etching, low series resistance Rs and high conversion efficiency, and an electrode prepared using the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A composition for a solar cell electrode, the composition comprising:
a conductive powder;
a glass frit that contains tellurium (Te), lithium (Li), zinc (Zn), and oxygen (O), the glass frit having a tap density of about 0.8 g/ml to about 1.55 g/ml; and
an organic vehicle.

2. The composition for a solar cell electrode as claimed in claim 1, wherein the glass frit is formed of a metal oxide including:
about 25 mol % to about 45 mol % of tellurium oxide (TeO₂);
about 25 mol % to about 40 mol % of lithium oxide (Li₂O); and
about 15 mol % to about 35 mol % of zinc oxide (ZnO).

3. The composition for a solar cell electrode as claimed in claim 1, wherein the glass frit is formed of a mixture of components that consists essentially of:
34 mol % to 39 mol % of tellurium oxide (TeO₂);
24 mol % to 33 mol % of lithium oxide (Li₂O);
17 mol % to 22 mol % of zinc oxide (ZnO);
7 mol % to 12 mol % of boron oxide (B₂O₃);
5 mol % to 7 mol % of magnesium oxide (MgO₂); and
0 mol % to 1 mol % of tungsten oxide (WO₃), provided that mole percentages of the TeO₂, Li₂O, ZnO, B₂O₃, MgO₂, and WO₃ are limited to combinations thereof providing a tap density of about 0.8 g/ml to about 1.55 g/ml.

4. The composition for a solar cell electrode as claimed in claim 1, wherein the glass frit is formed of a metal oxide including tellurium oxide (TeO₂), lithium oxide (Li₂O), and zinc oxide (ZnO), and wherein the glass fit satisfies the following Formula 1, wherein M_{TeO2} represents mol % of TeO₂, M_{Li2O} represents mol % of Li₂O, and M_{ZnO} represents mol % of ZnO,
0 mol %≤|M_{TeO2}−M_{Li2O}|+|M_{Li2O}−M_{ZnO}|+|M_{ZnO}−M_{TeO2}|≤about 60 mol %. [Formula 1]

5. The composition for a solar cell electrode as claimed in claim 1, wherein the glass frit does not include bismuth (Bi) and does not include lead (Pb).

6. The composition for a solar cell electrode as claimed in claim 1, wherein the glass frit has a particle size of about 0.1 μm to about 10 μm.

7. The composition for a solar cell electrode as claimed in claim 1, wherein the glass frit further includes at least one of sodium (Na), phosphorous (P), germanium (Ge), gallium (Ga), cerium (Ce), iron (Fe), silicon (Si), tungsten (W), magnesium (Mg), molybdenum (Mo), cesium (Cs), strontium (Sr), titanium (Ti), tin (Sn), indium (In), vanadium (V), barium (Ba), nickel (Ni), copper (Cu), potassium (K), arsenic (As), cobalt (Co), zirconium (Zr), manganese (Mn), aluminum (Al), or boron (B).

8. The composition for a solar cell electrode as claimed in claim 1, comprising:
about 60 wt % to about 95 wt % of the conductive powder;
about 0.1 wt % to about 20 wt % of the glass frit; and
about 1 wt % to about 30 wt % of the organic vehicle.

9. The composition for a solar cell electrode as claimed in claim 1, further comprising at least one of a dispersing agent, a thixotropic agent, a plasticizer, a viscosity stabilizer, an antifoaming agent, a pigment, an ultraviolet stabilizer, an antioxidant, or a coupling agent.

10. A solar cell electrode prepared from the composition for a solar cell electrode as claimed in claim 1.

11. A method of preparing a solar cell electrode, the method comprising:
providing a substrate having a p-n junction, the substrate having a light-receiving surface and a back surface;
applying, to the light-receiving surface, the composition as claimed in claim 1; and
baking the substrate having the composition applied thereto.
